(19) United States
(12) Patent Application Publication
(10) Pub. No.: US 2022/0195583 A1
(43) Pub. Date: Jun. 23, 2022

(54) SPUTTERING TARGET

(71) Applicant: MITSUBISHI MATERIALS CORPORATION, Tokyo (JP)

(72) Inventors: Yujiro Hayashi, Sanda-shi (JP); Yuichi Kondo, Sanda-shi (JP); Masahiro Shoji, Sanda-shi (JP)

(73) Assignee: MITSUBISHI MATERIALS CORPORATION, Tokyo (JP)

(21) Appl. No.: 17/441,705

(22) PCT Filed: Mar. 11, 2020
(86) PCT No.: PCT/JP2020/010442

§ 371 Date: Sep. 22, 2021

(30) Foreign Application Priority Data
Mar. 27, 2019 (JP) 2019-060492

(51) Int. Cl. C23C 14/34; C22C 1/05; C22C 1/10; C22C 30/00; H01J 37/34

(52) U.S. Cl. CPC C23C 14/3407; C22C 1/05; H01J 37/3429; C22C 30/00; C22C 1/10

(57) ABSTRACT

A sputtering target including Ge, Sb, and Te, in which a content of C is set in a range of 0.2 atom % or more and 10 atom % or less, an oxygen content is set to 1000 ppm or less by mass, carbon particles are dispersed in a Ge—Sb—Te phase, and an average particle size of the carbon particles is in a range of more than 0.5 μm and 5.0 μm or less.

### TECHNICAL FIELD

The present invention relates to a sputtering target used when forming a Ge—Sb—Te alloy film able to be used as a recording film for a phase change recording medium or a semiconductor non-volatile memory, for example.

Priority is claimed on Japanese Patent Application No. 2019-060492, filed in Japan on Mar. 27, 2019, the content of which is incorporated herein by reference.

### BACKGROUND ART

Generally, in phase change recording media such as DVD-RAM, semiconductor non-volatile memory (Phase Change RAM (PCRAM)), and the like, a recording film formed of a phase change material is used. In a recording film formed of such a phase change material, reversible phase change between crystal and amorphous is caused by heating by laser light irradiation or Joule heat and the difference of reflectivity or electrical resistance between crystal and amorphous is made to correspond to 1 and 0, thereby realizing non-volatile storage.

As a recording film formed of a phase change material, a Ge—Sb—Te alloy film is widely used.

The Ge—Sb—Te alloy film described above is formed using a sputtering target, for example, as shown in Patent Documents 1 to 5.

In the sputtering targets described in Patent Documents 1 to 5, an ingot of a Ge—Sb—Te alloy having a desired composition is prepared, the ingot is pulverized to obtain a Ge—Sb—Te alloy powder, and the obtained Ge—Sb—Te alloy powder is pressed and sintered, that is, by a powder sintering method, to carry out the manufacturing.

Patent Document 1 proposes a technique for suppressing the generation of abnormal discharge by having no pores having an average diameter of 1 μm or more present and limiting the number of pores present in a sintered body such that the number of pores having an average diameter of 0.1 to 1 μm is 100 or less per 4000 μm².

Patent Document 2 discloses that the total amount of carbon, nitrogen, oxygen, and sulfur, which are gas components, is limited to 700 ppm or less.

Patent Documents 3 and 4 propose a technique for suppressing the generation of cracks when sputtering is performed at a high output by setting the oxygen concentration in the sputtering target to 5000 wtppm or more.

Patent Document 5 proposes a technique for suppressing the generation of abnormal discharge and suppressing cracks in a sputtering target by specifying the oxygen content as 1500 to 2500 wtppm and specifying the average particle size of the oxide.

### CITATION LIST

### Patent Documents

### [Patent Document 1]

Japanese Patent No. 4885305

### [Patent Document 2]

Japanese Patent No. 5420594

### [Patent Document 3]

Japanese Patent No. 5394481

### [Patent Document 4]

Japanese Patent No. 5634575

### [Patent Document 5]

Japanese Patent No. 6037421

### SUMMARY OF INVENTION

### Technical Problem

As described in Patent Document 1, in a case where the number of pores is limited, it is not possible to alleviate thermal stress generated during bonding to the backing material and there was a concern that cracks may be generated during bonding.

As described in Patent Document 2, even in a case where the oxygen content is limited to a low amount and the number of pores is reduced as a result, there was a concern that cracks may be generated during bonding to a backing material.

On the other hand, in a case where the oxygen concentration is set as high as 5000 wtppm or more as in Patent Documents 3 and 4, there was a concern that abnormal discharge may be easily generated during sputtering and stable sputtering film formation may not be possible. In addition, at the time of bonding, there was a concern that it may not be possible to suppress the generation of cracks due to thermal expansion.

Although Patent Document 5 specifies the oxygen content and specifies the particle size of the oxide, there was a concern that it may not be possible to sufficiently suppress the generation of abnormal discharge and it may not be possible to sufficiently suppress the generation of cracks during bonding to the backing material.

The invention is created in consideration of the circumstances described above and has an object of providing a sputtering target with which it is possible to sufficiently suppress the generation of abnormal discharge, to sufficiently suppress the generation of cracks during bonding to a backing material, and to stably form a Ge—Sb—Te alloy film.

### Solution to Problem

In order to solve the problems described above, the present inventors carried out intensive studies and, as a result, obtained the finding that, by dispersing carbon particles of a predetermined size in a Ge—Sb—Te phase, thermal stress during bonding is alleviated by the carbon particles and it is possible to suppress the generation of cracks during bonding.

In the present invention, the present invention is created based on the findings described above and the sputtering target according to one aspect of the present invention is a sputtering target including Ge, Sb, and Te, in which a content of C is set in a range of 0.2 atom % or more and 10 atom % or less, an oxygen content is set to 1000 ppm or less by mass, carbon particles are dispersed in a Ge—Sb—Te phase, and an average particle size of the carbon particles is set in a range of more than 0.5 μm and 5.0 μm or less.

According to the sputtering target according to one aspect of the present invention, the carbon particles with an average particle size in a range of more than 0.5 μm and 5.0 μm or less are dispersed in the Ge—Sb—Te phase, thus, the thermal stress during bonding is alleviated by the carbon particles and it is possible to suppress the generation of cracks during bonding.

In addition, in the sputtering target according to one aspect of the present invention, since the content of C is in the range described above, the number of carbon particles described above is sufficiently secured, thermal stress during bonding is alleviated by the carbon particles, and it is possible to reliably suppress the generation of cracks during bonding. In addition, the carbon particles are not dispersed more than necessary and it is possible to suppress the generation of abnormal discharge during sputtering caused by the carbon particles.

Furthermore, in the sputtering target according to one aspect of the present invention, since the oxygen content is limited to 1000 ppm or less by mass, it is possible to suppress the generation of abnormal discharge during sputtering. In addition, having the carbon particles described above makes it possible to sufficiently suppress the generation of cracks when sputtering at a high output, even in a case where the oxygen content is set to be low.

In the sputtering target according to one aspect of the present invention, preferably, the number density of the carbon particles is in a range of 1×10³ particles/mm² or more and 150×10³ particles/mm² or less.

In this case, since the number density of carbon particles is set in the range described above, the number of carbon particles is sufficiently ensured, thermal stress during bonding is alleviated by the carbon particles, and it is possible to reliably suppress the generation of cracks during bonding. In addition, the carbon particles are not dispersed more than necessary and it is possible to suppress the generation of abnormal discharge during sputtering caused by the carbon particles.

In addition, in the sputtering target according to one aspect of the present invention, preferably, the sputtering target of the aspect further contains one or two or more additive elements selected from In, Si, Ag, and Sn, and a total content of the additive elements is 25 atom % or less.

In this case, since it is possible to improve various characteristics of the sputtering target and the formed Ge—Sb—Te alloy film by appropriately adding the additive elements described above, such addition may be carried out as appropriate according to the required characteristics. In a case where the additive elements described above are added, it is possible to sufficiently ensure the basic characteristics of the sputtering target and the formed Ge—Sb—Te alloy film by limiting the total content of the additive elements to 25 atom % or less.

A method for manufacturing a sputtering target according to one aspect of the present invention has an ingot forming step in which a Ge raw material, an Sb raw material, and a Te raw material are melted to obtain a Ge—Sb—Te alloy ingot, a Ge—Sb—Te alloy powder forming step in which the Ge—Sb—Te alloy ingot is pulverized to obtain a Ge—Sb—Te alloy powder with an average particle size in a range of 0.5 μm or more and 5.0 μm or less, a mixing step in which the Ge—Sb—Te alloy powder is mixed with a carbon powder to obtain a raw material powder in which a ratio B/A×100(%) of the average particle size A of the Ge—Sb—Te alloy powder and the average particle size B of the carbon powder is in a range of 80% or more and 110% or less, and a sintering step in which the raw material powder is heated and sintered under pressure.

In the mixing step, a carbon powder with an average particle size in a range of 0.45 μm or more and 6.25 μm or less is preferably used.

In the mixing step, preferably, the Ge—Sb—Te alloy powder and the carbon powder are sealed together with ZrO₂ balls in a container of a ball mill device substituted with Ar or N₂ and mixed to obtain a raw material powder. The conditions of the ball mill are preferably in a range of 50 rpm or higher and 150 rpm or lower for the rotation speed. In addition, the rotation time is preferably in a range of 2 hours or more and 25 hours or less.

In the sintering step, the pressurizing pressure is preferably in a range of 5.0 MPa or more and 15.0 MPa or less.

In the sintering step, preferably, the temperature is held in a low temperature region of 280° C. or higher and 350° C. or lower for 1 hour or more and 6 hours or less and then the temperature is raised to a sintering temperature of 570° C. or higher and 590° C. or lower and held for 5 hours or more and 15 hours or less.

### Advantageous Effects of Invention

According to the present invention, it is possible to provide a sputtering target with which it is possible to sufficiently suppress the generation of abnormal discharge, to sufficiently suppress the generation of cracks during bonding to a backing material, and to stably form a Ge—Sb—Te alloy film.

### BRIEF DESCRIPTION OF DRAWINGS

FIG. 1A is an SEM image showing the structure of a sputtering target which is an embodiment of the present invention at 300× magnification.

FIG. 1B is an SEM image showing the structure of a sputtering target which is an embodiment of the present invention at 3000× magnification.

FIG. 2 is a flow chart showing a method for manufacturing a sputtering target which is an embodiment of the present invention.

### DESCRIPTION OF EMBODIMENTS

A description will be given below of the sputtering target which is an embodiment of the present invention with reference to the drawings.

The sputtering target of the present embodiment is used, for example, when forming a Ge—Sb—Te alloy film used as a phase change recording film of a phase change recording medium or a semiconductor non-volatile memory.

In the sputtering target of the present embodiment, Ge, Sb, and Te are contained as the main components, the content of C is set in a range of 0.2 atom % or more and 10 atom % or less, and the oxygen content is limited to 1000 ppm or less by mass.

In the present embodiment, except for gas components such as C and O, the composition is set such that the content of Ge is in a range of 10 atom % or more and 30 atom % or less, the content of Sb is in a range of 15 atom % or more and 35 atom % or less, and the remainder is Te and unavoidable impurities. By setting such a composition, it is possible to form a phase change recording film having desirable characteristics.

In the sputtering target of the present embodiment, the content of Ge is more preferably 15 atom % or more and 25 atom % or less, and even more preferably 20 atom % or more and 23 atom % or less. The content of Sb is more preferably 15 atom % or more and 25 atom % or less, and even more preferably 20 atom % or more and 23 atom % or less. The content of Te is more preferably 40 atom % or more and 65 atom % or less, and even more preferably 53 atom % or more and 57 atom % or less.

The total content of the elements described above may include unavoidable impurities with an upper limit of 100 atom %.

The lower limit of the content of C is more preferably 0.5 atom % or more, and even more preferably 1.0 atom % or more. The upper limit of the content of C is more preferably 6.0 atom % or less, and even more preferably 5.0 atom % or less.

In addition, the upper limit of the oxygen content is more preferably 800 ppm or less by mass, and even more preferably 600 ppm or less. The lower limit of the oxygen content is not particularly limited but is more preferably 50 ppm or more by mass, and even more preferably 100 ppm or more by mass.

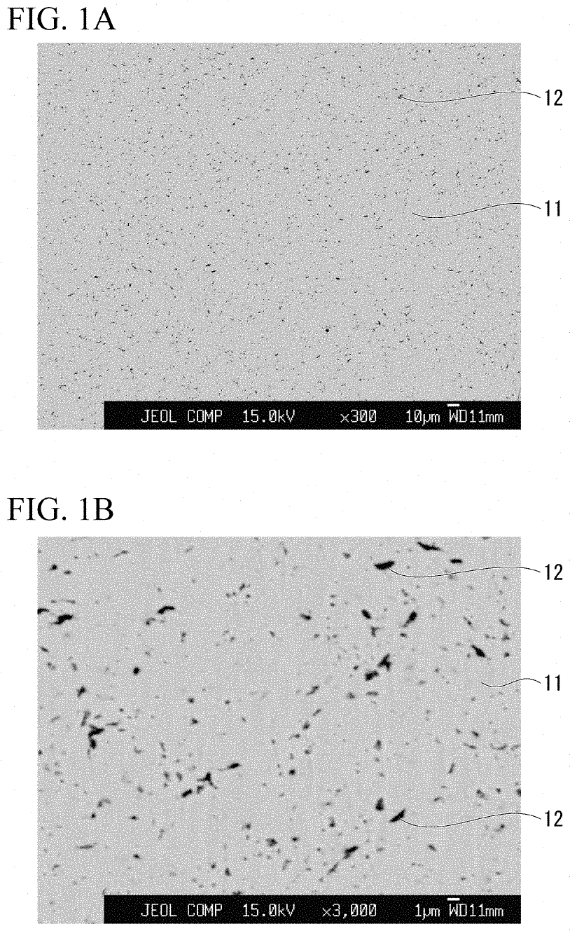

In the sputtering target of the present embodiment, FIG. 1A and FIG. 1B show a structure in which carbon particles 12 are dispersed in a Ge—Sb—Te phase 11, in which the average particle size of the carbon particles 12 is in a range of more than 0.5 μm and 5.0 μm or less.

The lower limit of the average particle size of the carbon particles 12 is more preferably 0.7 μm or more, and even more preferably 1.0 μm or more. The upper limit of the average particle size of the carbon particles 12 is more preferably 4.0 μm or less, and even more preferably 3.0 μm or less.

In addition, in the present embodiment, the number density of the carbon particles 12 is preferably in a range of 1×10³ particles/mm² or more and 150×10³ particles/mm² or less. The number density is defined by converting the number of carbon particles appearing on the observation surface of the sputtering target into the number per unit area. The lower limit of the number density of carbon particles 12 is more preferably 2×10³ particles/mm² or more, and even more preferably 3×10³ particles/mm² or more.

The upper limit of the number density of the carbon particles 12 is more preferably 120×10³ particles/mm² or less, and even more preferably 100×10³ particles/mm² or less.

In addition, the sputtering target of the present embodiment may contain, in addition to Ge, Sb, and Te, if necessary, one or two or more additive elements selected from In, Si, Ag, and Sn. In a case where the additive elements described above are added, the total content of the additive elements is set to 25 atom % or less.

In a case where the additive elements are added in the sputtering target of the present embodiment, the total content of the additive elements is preferably 20 atom % or less, and more preferably 15 atom % or less. In addition, the lower limit value of the additive elements is not particularly limited, but is preferably 3 atom % or more, and more preferably 5 atom % or more, in order to reliably improve various characteristics.

In the sputtering target of the present embodiment, the Ge—Sb—Te phase 11 has a structure in which, in a matrix of a low-oxygen region in which the oxygen concentration is low, high-oxygen regions, which have a higher oxygen concentration than the low-oxygen region, are dispersed in island form. This structure makes it possible to further suppress the generation of cracks.

In addition, in the sputtering target of the present embodiment, the ratio b/a×100(%) of an average crystal particle size of the Ge—Sb—Te phase 11 and an average particle size b of the carbon particles 12 is preferably in a range of 80% or more and 110% or less.

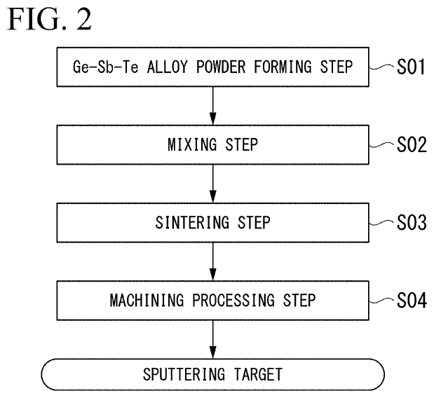

Next, a description will be given of a method for manufacturing a sputtering target of the present embodiment with reference to the flow chart of FIG. 2.

### (Ge—Sb—Te Alloy Powder Forming Step S01)

First, the Ge raw material, the Sb raw material, and the Te raw material are weighed so as to have a predetermined blending ratio. It is preferable to use a Ge raw material, an Sb raw material, and a Te raw material having a purity of 99.9 mass % or more, respectively.

The blending ratio of the Ge raw material, the Sb raw material, and the Te raw material is appropriately set according to the Ge—Sb—Te alloy film to be formed.

The Ge raw material, the Sb raw material, and the Te raw material weighed as described above are charged into a melting furnace and melted. The Ge raw material, the Sb raw material, and the Te raw material are melted in a vacuum or in an inert gas atmosphere (for example, Ar gas). In the case of melting in a vacuum, the degree of vacuum is preferably 10 Pa or less. In the case of melting in an inert gas atmosphere, it is preferable to perform vacuum replacement up to 10 Pa or less and then introduce an inert gas (for example, Ar gas).

The obtained molten metal is poured into an iron mold to obtain a Ge—Sb—Te alloy ingot. The casting method is not particularly limited.

This Ge—Sb—Te alloy ingot is pulverized in an atmosphere of an inert gas using a hammer mill device to obtain a Ge—Sb—Te alloy powder having an average particle size in a range of 0.5 nm or more and 5.0 μm or less. The average particle size of the Ge—Sb—Te alloy powder is more preferably 0.75 μm or more and 4.0 μm or less, and even more preferably 1.0 μm or more and 3.0 μm or less. The pulverizing method is not limited to a hammer mill and other pulverizing methods such as manual pulverizing in a mortar may be applied.

### (Mixing Step S02)

Next, a carbon powder with an average particle size in a range of 0.45 μm or more and 6.25 μm or less is prepared. The average particle size of the carbon powder is more preferably 0.6 μm or more and 4.4 μm or less, and even more preferably 0.8 μm or more and 3.3 μm or less. The ratio B/A×100(%) of the average particle size A of the Ge—Sb—Te alloy powder and the average particle size B of the carbon powder is more preferably in a range of 80% or more and 110% or less. That is, it is preferable to prepare the Ge—Sb—Te alloy powder and carbon powder such that the average particle size A of the Ge—Sb—Te alloy powder and the average particle size B of the carbon powder approximate each other.

The raw material powder is obtained by sealing and mixing the Ge—Sb—Te alloy powder and carbon powder described above together with ZrO₂ balls in a container of a ball mill device substituted with Ar or N₂. If necessary, powders of one or two or more additive elements selected from In, Si, Ag, and Sn may be added.

In addition, the conditions of the ball mill are preferably in a range of 50 rpm or higher and 150 rpm or lower for the rotation speed. A rotation speed of 60 rpm or higher and 120 rpm or lower is more preferable, and 80 rpm or higher and 100 rpm or lower is even more preferable. In addition, the rotation time is preferably in a range of 2 hours or more and 25 hours or less. A rotation time of 10 hours or more and 20 hours or less is more preferable, and 12 hours or more and 18 hours or less is even more preferable. Setting a rotation speed of 50 rpm or higher and a rotation time of 2 hours or more makes it possible to sufficiently mix the Ge—Sb—Te alloy powder and carbon powder. In addition, setting the rotation time to 25 hours or less makes it possible to suppress the mixing in of oxygen and inhibit an increase in the oxygen content.

### (Sintering Step S03)

Next, the raw material powder obtained as described above is filled in a molding die and heated and sintered under pressure to obtain a sintered body. As the sintering method, it is possible to apply hot pressing, HIP, or the like. In the present embodiment, hot pressing is adopted. The pressurizing pressure is in a range of 5.0 MPa or more and 15.0 MPa or less.

In the sintering step S03, by holding for 1 hour or more and 6 hours or less in a low temperature region of 280° C. or higher and 350° C. or lower, water on the surface of the raw material powder is removed, then the temperature is raised to a sintering temperature of 570° C. or higher and 590° C. or lower and held for 5 hours or more and 15 hours or less to proceed with the sintering.

The lower limit of the holding time in the low temperature region in the sintering step S03 is more preferably 1.5 hours or more, and even more preferably 2 hours or more. On the other hand, the upper limit of the holding time in the low temperature region in the sintering step S03 is more preferably 5.5 hours or less, and even more preferably 5 hours or less.

In addition, the lower limit of the holding time at the sintering temperature in the sintering step S03 is more preferably 7 hours or more, and even more preferably 8 hours or more. On the other hand, the upper limit of the holding time at the sintering temperature in the sintering step S03 is more preferably less than 14 hours, and even more preferably less than 12 hours.

Furthermore, the lower limit of the pressurizing pressure in the sintering step S03 is preferably 7.5 MPa or more, and more preferably 9.0 MPa or more. On the other hand, the upper limit of the pressurizing pressure in the sintering step S03 is preferably 12.5 MPa or less, and more preferably 11.0 MPa or less.

### (Machining Processing Step S04)

Next, the obtained sintered body is subjected to machining processing so as to have a predetermined size.

The sputtering target of the present embodiment is manufactured by the above steps.

According to the sputtering target of the present embodiment with the above configuration, carbon particles 12 are dispersed in the Ge—Sb—Te phase and the average particle size of the carbon particles 12 is set to be more than 0.5 μm, thus, it is possible to alleviate thermal stress during bonding by the carbon particles 12 and to suppress the generation of cracks during bonding. On the other hand, since the average particle size of the carbon particles 12 is 5.0 μm or less, it is possible to suppress the generation of particles.

In addition, it is possible to sufficiently suppress the generation of cracks during bonding without increasing the oxygen content.

In addition, in the sputtering target of the present embodiment, since the content of C is set in a range of 0.2 atom % or more and 10 atom % or less, the number of carbon particles 12 described above is sufficiently ensured, it is possible to alleviate thermal stress during bonding by the carbon particles 12 and to reliably suppress the generation of cracks during bonding. In addition, since the content of C is limited to 10 atom % or less, the carbon particles 12 are not dispersed more than necessary and it is possible to suppress the generation of abnormal discharge during sputtering caused by the carbon particles 12.

Furthermore, in the sputtering target of the present embodiment, the oxygen content is limited to 1000 ppm or less by mass, thus, it is possible to suppress the generation of abnormal discharge during sputtering. In addition, since the sputtering target has the carbon particles 12 as described above, it is possible to sufficiently suppress the generation of cracks when sputtering at a high output, even in a case where the oxygen content is limited to 1000 ppm or less by mass.

In addition, in the sputtering target of the present embodiment, in a case where the number density of the carbon particles 12 is set in a range of 1×10³ particles/mm² or more and 150×10³ particles/mm² or less, the number of the carbon particles 12 is ensured, it is possible to sufficiently alleviate the thermal stress during bonding by the carbon particles 12, and it is possible to reliably suppress the generation of cracks during bonding. In addition, the carbon particles 12 are not dispersed more than necessary and it is possible to suppress the generation of abnormal discharge during sputtering caused by the carbon particles 12.

In addition, in a case where the sputtering target of the present embodiment further contains one or two or more additive elements selected from C, In, Si, Ag, and Sn, and the total content of the additive elements is 25 atom % or less, it is possible to improve various characteristics of the sputtering target and the formed Ge—Sb—Te alloy film and to sufficiently ensure the basic characteristics of the sputtering target and the formed Ge—Sb—Te alloy film.

For example, since the Ge—Sb—Te alloy film of the present embodiment is used as a recording film, the additive elements described above may be appropriately added so as to obtain appropriate chemical, optical, and electrical response as the recording film.

In addition, in the present embodiment, in the mixing step S02, the ratio B/A×100(%) of the average particle size A of the Ge—Sb—Te alloy powder and the average particle size B of the carbon powder is set in a preferable range of 80% or more and 110% or less and the Ge—Sb—Te alloy powder and the carbon powder are selected such that the average particle size A of the Ge—Sb—Te alloy powder and the average particle size B of the carbon powder approximate each other, thus, it is possible to uniformly disperse the carbon particles 12. The ratio B/A×100(%) of the average particle size A of the Ge—Sb—Te alloy powder and the average particle size B of the carbon powder is more preferably in a range of 90% or more and 100% or less.

Since the crystal particle size of the Ge—Sb—Te phase 11 depends on the particle size of the Ge—Sb—Te alloy powder described above, in the sputtering target of the present embodiment, as described above, the ratio b/a×100(%) of the average crystal particle size a of the Ge—Sb—Te phase 11 and the average particle size b of the carbon particles 12 is in a range of 80% or more and 110% or less. The ratio b/a×100(%) of the average crystal particle size a of the Ge—Sb—Te phase 11 to the average particle size b of the carbon particles 12 is more preferably in a range of 85% or more and 105% or less.

Although the embodiments of the present invention are described above, the present invention is not limited thereto and it is possible to make appropriate changes within a range not departing from the technical idea of the invention.

For example, in the present embodiment, the Ge—Sb—Te phase is described as a structure in which, in a matrix of a low-oxygen region which has a low oxygen concentration, high-oxygen regions, which have a higher oxygen concentration than the low-oxygen region, are dispersed in island form; however, without being limited thereto, the structure may be a structure in which the oxygen concentration is uniform or a structure in which low-oxygen regions are dispersed in island form in a matrix of the high-oxygen region.

### EXAMPLES

A description will be given below of the results of confirmation experiments performed to confirm the effectiveness of the present invention.

### (Sputtering Target)

As melted raw materials, Ge raw materials, Sb raw materials, and Te raw materials each having a purity of 99.9 mass % or more were prepared.

The Ge raw materials, Sb raw materials, and Te raw materials were weighed so as to have predetermined blending ratios, charged into a melting furnace, and melted in an Ar gas atmosphere and the obtained molten metal was poured into an iron mold to obtain Ge—Sb—Te alloy ingots.

The obtained Ge—Sb—Te alloy ingots were pulverized using a hammer mill in an Ar gas atmosphere and sieved to obtain Ge—Sb—Te alloy powders with the average particle sizes shown in Table 1.

Then, as shown in Table 1, the carbon powder of the average particle sizes, the Ge—Sb—Te alloy powder described above, and, if necessary, additive element powder were weighed so as to be at the blending ratios shown in Table 1. Then, the weighed carbon powder, Ge—Sb—Te alloy powder, and additive element powder, together with ZrO₂ balls, were charged into a container of a ball mill device, which was substituted with Ar gas, and mixed under the conditions shown in Table 1.

The average particle sizes of the Ge—Sb—Te alloy powder and carbon powder were measured as follows.

A dispersion solution was adjusted by adding an appropriate amount of each powder to an aqueous sodium hexametaphosphate solution (0.2 mol %). The particle size distribution of the powders in the dispersion solution was measured using a particle size distribution analyzer (Microtrac MT3000 manufactured by Nikkiso Co., Ltd.) and the median diameter thereof was calculated. This median diameter is listed in Table 1 as the “average particle size”.

Next, the obtained raw material powder was filled into a hot press molding die made of carbon and held at 300° C. for 2 hours in a state of being pressured at a pressurizing pressure of 10.0 MPa in a vacuum atmosphere and then the temperature was raised to the sintering temperature of 580° C. and held for 12 hours to obtain a sintered body.

The obtained sintered body was subjected to machining processing to manufacture a sputtering target (φ152.4 mm×6 mm) for evaluation.

The obtained sputtering targets were evaluated for the following items. The evaluation results are shown in Table 2.

### (Component Composition)

A measurement sample was taken from the obtained sputtering target and C and O were measured by the inert gas melting-infrared absorption method. Elements other than C and O were measured by ICP emission spectrometry.

### (Average Particle Size/Number Density of Carbon Particles)

An observation sample was taken from the obtained sputtering target, an elemental mapping image observed by EPMA at a magnification of 3000× was binarized using image processing software, the equivalent circle diameter of the carbon particles was measured from the binarized image, and the average particle size was calculated. As the equivalent circle diameter, a diameter d of a circle of the same area as an area S of each carbon particle was set as the equivalent circle diameter (calculated from S=πd²).

In addition, the number density of carbon particles (particles/mm²) was calculated by counting the number of carbon particles from the binarized image in the elemental mapping image described above and dividing the result by the area of the mapping image.

### (Cracks During Bonding)

The sputtering target described above was bonded to a backing plate made of Cu using In solder. The bonding was performed under conditions in which the heating temperature was 200° C., the applied load was 3 kg, and the cooling was natural cooling. A case in which no cracks were confirmed in the bonding was evaluated as “A” and a case in which cracks were confirmed in the bonding was evaluated as “B”.

### (Abnormal Discharge)

The sputtering target described above, in which cracking was not confirmed, was attached to a magnetron sputtering apparatus and, after carrying out exhaust to 1×10⁻⁴ Pa, sputtering was carried out under conditions of an Ar gas pressure of 0.3 Pa, an input power of DC 500 W, and a target-board distance of 70 nm.

The number of abnormal discharges during sputtering was measured as the number of abnormal discharges in one hour from the start of discharge, by the arc count function of a DC power supply (model number: RPDG-50A) manufactured by MKS Instruments.

TABLE 1

| | | | | | | | | | | Average particle size | | | | |
|---|---|---|---|---|---|---|---|---|---|---|---|---|---|---|
| | | Blending ratio (atom %) | | | | | | | | of raw material powder | | | Ball mill | |
| | | | | | | Additive elements | | | | GeSbTe alloy | Carbon powder | B/A | Time | Rotation speed |
| | | Ge | Sb | Te | C | In | Si | Ag | Sn | powder A (μm) | B (μm) | (%) | (h) | (rpm) |
| Invention | 1 | 22.0 | 22.0 | 55.0 | 1.0 | — | — | — | — | 2.5 | 2.5 | 100 | 15 | 100 |
| Examples | 2 | 22.0 | 22.0 | 55.8 | 0.2 | — | — | — | — | 2.6 | 2.5 | 96 | 15 | 100 |
| | 3 | 20.0 | 20.0 | 50.0 | 10.0 | — | — | — | — | 2.4 | 2.4 | 100 | 15 | 100 |
| | 4 | 22.0 | 22.0 | 55.0 | 1.0 | — | — | — | — | 4.8 | 4.9 | 102 | 2 | 100 |
| | 5 | 22.0 | 22.0 | 55.0 | 1.0 | — | — | — | — | 4.7 | 4.3 | 91 | 15 | 50 |
| | 6 | 20.0 | 20.0 | 50.0 | 5.0 | 5.0 | — | — | — | 2.6 | 2.5 | 96 | 15 | 100 |
| | 7 | 16.0 | 16.0 | 38.0 | 5.0 | 25.0 | — | — | — | 2.5 | 2.6 | 104 | 15 | 100 |
| | 8 | 20.0 | 20.0 | 50.0 | 5.0 | — | 5.0 | — | — | 2.4 | 2.5 | 104 | 15 | 100 |
| | 9 | 20.0 | 20.0 | 50.0 | 5.0 | — | — | 5.0 | — | 2.6 | 2.6 | 100 | 15 | 100 |
| | 10 | 20.0 | 20.0 | 50.0 | 5.0 | — | — | — | 5.0 | 2.5 | 2.4 | 96 | 15 | 100 |
| | 11 | 22.0 | 22.0 | 55.0 | 1.0 | — | — | — | — | 0.7 | 0.6 | 86 | 25 | 150 |
| | 12 | 22.0 | 22.0 | 55.0 | 1.0 | — | — | — | — | 2.5 | 2.6 | 104 | 8 | 150 |
| Comparative | 1 | 22.0 | 22.0 | 55.0 | 1.0 | — | — | — | — | 5.0 | 5.2 | 104 | 1 | 100 |
| Examples | 2 | 20.0 | 20.0 | 49.0 | 11.0 | — | — | — | — | 2.6 | 2.6 | 100 | 15 | 100 |
| | 3 | 22.3 | 22.3 | 55.3 | 0.1 | — | — | — | — | 2.5 | 2.5 | 100 | 15 | 100 |
| | 4 | 22.0 | 22.0 | 55.0 | 1.0 | — | — | — | — | 0.6 | 0.4 | 67 | 25 | 175 |
| | 5 | 22.0 | 22.0 | 55.0 | 1.0 | — | — | — | — | 2.5 | 2.6 | 104 | 30 | 100 |

TABLE 2

| | | | | | | | | | | | Carbon particles | | | Number of |
|---|---|---|---|---|---|---|---|---|---|---|---|---|---|---|
| | | Composition of sputtering | | | | | | | | Oxygen | | Number | | generations |
| | | target (atom %) | | | | | | | | content | Average | density | Cracks | of abnormal |
| | | | | | | Additive elements | | | | mass ratio | particle | (particles/ | during | discharges |
| | | Ge | Sb | Te | C | In | Si | Ag | Sn | (ppm) | size (μm) | mm²) | bonding | (times/h) |
| Invention | 1 | 21.8 | 22.4 | 54.9 | 0.9 | — | — | — | — | 800 | 2.3 | 16 × 10³ | A | 3 |
| Examples | 2 | 21.9 | 22.4 | 55.5 | 0.2 | — | — | — | — | 1000 | 2.4 | 3 × 10³ | A | 8 |
| | 3 | 20.0 | 20.0 | 50.1 | 9.9 | — | — | — | — | 700 | 2.4 | 115 × 10³ | A | 9 |
| | 4 | 22.1 | 21.8 | 55.0 | 1.1 | — | — | — | — | 600 | 4.8 | 13 × 10³ | A | 8 |
| | 5 | 22.0 | 22.2 | 54.8 | 1.0 | — | — | — | — | 800 | 4.4 | 13 × 10³ | A | 7 |
| | 6 | 20.1 | 19.9 | 49.9 | 5.0 | 5.1 | — | — | — | 900 | 2.4 | 42 × 10³ | A | 7 |
| | 7 | 16.3 | 15.9 | 38.1 | 4.7 | 25.0 | — | — | — | 800 | 2.4 | 38 × 10³ | A | 6 |
| | 8 | 20.0 | 19.9 | 50.1 | 4.9 | — | 5.1 | — | — | 800 | 2.3 | 44 × 10³ | A | 6 |
| | 9 | 19.8 | 19.9 | 50.1 | 5.1 | — | — | 5.2 | — | 700 | 2.4 | 40 × 10³ | A | 2 |
| | 10 | 20.1 | 20.1 | 49.9 | 5.0 | — | — | — | 4.9 | 800 | 2.4 | 41 × 10³ | A | 4 |
| | 11 | 22.2 | 21.9 | 54.8 | 1.1 | — | — | — | — | 900 | 0.6 | 2 × 10³ | A | 2 |
| | 12 | 22.0 | 21.9 | 55.1 | 1.0 | — | — | — | — | 700 | 2.5 | 7 × 10³ | A | 2 |
| Comparative | 1 | 21.8 | 22.3 | 54.8 | 1.1 | — | — | — | — | 500 | 5.1 | 3 × 10³ | A | 15 |
| Examples | 2 | 20.1 | 20.2 | 48.7 | 11.0 | — | — | — | — | 700 | 2.5 | 161 × 10³ | A | 13 |
| | 3 | 22.3 | 22.3 | 55.3 | 0.1 | — | — | — | — | 700 | 2.4 | 5 × 10² | B | — |
| | 4 | 22.2 | 22.0 | 54.9 | 0.9 | — | — | — | — | 900 | 0.5 | 8 × 10² | B | — |
| | 5 | 21.9 | 22.2 | 54.9 | 1.0 | — | — | — | — | 1100 | 2.3 | 15 × 10³ | A | 10 |

In Comparative Example 1, in which the average particle size of the carbon particles dispersed in the Ge—Sb—Te phase was more than 5.0 μm, the number of abnormal discharges during sputtering was high at 15 times.

In Comparative Example 2, in which the content of C was more than 10 atom %, the number density of carbon particles became as high as 161×10³ particles/mm² and the number of abnormal discharges was high at 13 times.

In Comparative Example 3, in which the C content was less than 0.2 atom %, the number density of carbon particles became as low as 5×10² particles/mm² and cracks were generated during bonding.

In Comparative Example 4, in which the average particle size of the carbon particles dispersed in the Ge—Sb—Te phase was 0.5 μm or less, the number density of the carbon particles became as low as 8×10² particles/mm² and cracks were generated during bonding.

In Comparative Example 5, in which the oxygen content was more than 1000 ppm by mass, the number of abnormal discharges during sputtering was high at 10 times.

In contrast, in Invention Examples 1 to 12, in which the content of C was in a range of 0.2 atom % or more and 10 atom % or less, the oxygen content was 1000 ppm or less by mass, and the average particle size of the carbon particles dispersed in the Ge—Sb—Te phase was in a range of more than 0.5 μm and 5.0 μm or less, it was possible to suppress cracking during bonding. In addition, the number of generations of abnormal discharges was 9 times or less and it was possible to stably form a sputtering film.

As described above, according to the Invention Examples of the present invention, it is confirmed that it is possible to provide a sputtering target with which it is possible to sufficiently suppress the generation of abnormal discharge, to sufficiently suppress the generation of cracks during bonding to a backing material, and to stably form a Ge—Sb—Te alloy film.

### INDUSTRIAL APPLICABILITY

According to the present invention, it is possible to provide a sputtering target with which it is possible to sufficiently suppress the generation of abnormal discharge, to sufficiently suppress the generation of cracks during bonding to a backing material, and to stably form a Ge—Sb—Te alloy film.

### REFERENCE SIGNS LIST

11: Ge—Sb—Te phase
12: Carbon particles

1. A sputtering target comprising:
Ge;
Sb; and
Te,
wherein a content of C is set in a range of 0.2 atom % or more and 10 atom % or less,
an oxygen content is set to 1000 ppm or less by mass,
carbon particles are dispersed in a Ge—Sb—Te phase, and
an average particle size of the carbon particles is set in a range of more than 0.5 μm and 5.0 μm or less.

2. The sputtering target according to claim 1,
wherein a number density of the carbon particles is in a range of 1×10³ particles/mm² or more and 150×10³ particles/mm² or less.

3. The sputtering target according to claim 1, further comprising:
one or two or more additive elements selected from In, Si, Ag, and Sn,
wherein a total content of the additive elements is 25 atom % or less.

4. The sputtering target according to claim 2, further comprising:
one or two or more additive elements selected from In, Si, Ag, and Sn,
wherein a total content of the additive elements is 25 atom % or less.
